(19) United States
(12) Patent Application Publication
(10) Pub. No.: US 2013/0113085 A1
(43) Pub. Date: May 9, 2013

(54) Atomic Layer Deposition Of Films Using Precursors Containing Hafnium Or Zirconium

(71) Applicants: Timothy Michaelson, Milpitas, CA (US); Timothy W. Weidman, Sunnyvale, CA (US); Paul Deaton, San Jose, CA (US)

(72) Inventors: Timothy Michaelson, Milpitas, CA (US); Timothy W. Weidman, Sunnyvale, CA (US); Paul Deaton, San Jose, CA (US)

(73) Assignee: Applied Materials, Inc., Santa Clara, CA (US)

(21) Appl. No.: 13/289,657

(22) Filed: Nov. 4, 2011

(51) Int. Cl. H01L 21/314; H01L 29/00

(52) U.S. Cl. 257/632; 438/785; 257/E29.001; 257/E21.266

(57) ABSTRACT

Provided are low temperature methods of depositing hafnium or zirconium containing films using a Hf(BH₄)₄ precursor, or Zr(BH₄)₄ precursor, respectively, as well as a co-reactant. The co-reactant can be selected to obtain certain film compositions. Co-reactants comprising an oxidant can be used to deposit oxygen into the film. Accordingly, also provided are films comprising a metal, boron and oxygen, wherein the metal comprises hafnium where a Hf(BH₄)₄ precursor is used, or zirconium, where a Zr(BH₄)₄ precursor is used.

### TECHNICAL FIELD

Embodiments of the present invention generally relate to the deposition of hafnium and zirconium-containing films.

### BACKGROUND

Deposition of thin films on a substrate surface is an important process in a variety of industries including semiconductor processing, diffusion barrier coatings and dielectrics for magnetic read/write heads. In the semiconductor industry, in particular, miniaturization requires a level control of thin film deposition to produce conformal coatings on high aspect ratio structures. One method for deposition of thin films with such control and conformal deposition is atomic layer deposition (ALD). Most ALD processes are based on binary reaction sequences. Each of the two surface reactions occurs sequentially. Because the surface reactions are sequential, the two gas phase reactants are not in contact, and possible gas phase reactions that may form and deposit particles are limited. The typical approach to further ALD development has been to determine whether or not currently available chemistries are suitable for ALD. There is a need for new deposition chemistries that are commercially viable.

One useful application of ALD processes relates to self-aligned double patterning processes. A spacer is a conformal film layer formed on the sidewall of a pre-patterned feature. A spacer can be formed by conformal ALD of a film on a previous pattern, followed by anisotropic etching to remove all the film material on the horizontal surfaces, leaving only the material on the sidewalls. By removing the original patterned feature, only the spacer is left. However, since there are two spacers for every line, the line density becomes doubled. The spacer technique is applicable for defining narrow gates at half the original lithographic pitch, for example.

Methodology exists for the low temperature ALD of SiO₂ based films over photoresists for use as the spacer layers for self-aligned double patterning (SADP). However, such process flows are poorly suited to applications in which SiO₂-based films are also present as underlayers in the stack being patterned, as there will be insufficient etch selectivity. Common SiO₂ based underlayers include such films as spin-on siloxane based layers useful as antireflection coatings underneath a photoresist, or SiON layers, for example dielectric anti-reflective coating (DARC). Dielectric anti-reflective coating is a dielectric material that limits reflections from a substrate during photolithography steps, which would otherwise interfere with the patterning process. Thus, there is a need for low temperature ALD films that exhibit high dry etch selectivity relative to SiO₂-based films.

### SUMMARY

One aspect of the invention relates to a film on a substrate, the film comprising a hafnium, boron and oxygen. In a specific embodiment, the film may also comprise hydrogen. The film may be represented by an empirical formula of HfBₓO_{y}H. The value of x has may be from about 0 to about 4, y has a value of from about 0 to about 10, and z has a range of from about 0 to about 10. In a specific embodiment, the variable x has a value of about 2.

Another aspect of the invention relates to a method of depositing a metal-containing film. The method comprises sequentially exposing a substrate surface to alternating flows of a M(BH₄)₄ precursor and a co-reactant to provide a film, wherein M is a metal selected from hafnium and zirconium. In one embodiment, the co-reactant flow does not saturate the substrate surface. In another embodiment, the co-reactant comprises an oxidant. In a more specific embodiment, the oxidant is selected from H₂O, H₂O₂, O₂, O₃, and mixtures thereof. In one embodiment, M comprises hafnium. In a further embodiment, the co-reactant comprises an oxidant and the film comprises hafnium, boron and oxygen. In an alternative embodiment, M comprises zirconium. In a variant of this embodiment, the co-reactant comprises an oxidant and the film comprises zirconium, boron and oxygen. In an alternative embodiment, the co-reactant comprises NH₃. In a specific embodiment, M is hafnium, and the film comprises hafnium, boron and nitrogen.

In one embodiment of this aspect, the method is carried out at a temperature of less than about 200° C. In a more specific version of this embodiment, the temperature has a range of about room temperature to about 100° C. The method according to various embodiments of the invention may be used to deposit films onto a photoresist. In alternative embodiments, the co-reactant is selected from WF₆ and RuO₄. Accordingly, in one embodiment the deposited film comprises M, tungsten and boron. In another embodiment, the deposited film comprises M, ruthenium, boron and oxygen.

A third aspect of the invention relates to a method of depositing a metal-containing film. The method comprises sequentially exposing a substrate to alternating flows of a Hf(BH₄)₄ precursor and a co-reactant comprising an oxidant to provide a film.

### BRIEF DESCRIPTION OF THE DRAWINGS

FIGS. 1A-E are an illustration of a self-aligned double patterning process on a photoresist using an HfBOₓ film spacer deposited in accordance with an embodiment of the invention; and

FIG. 2 is a scanning electron microscope image of an HfBOₓ film deposited in accordance with an embodiment of the invention.

FIG. 3 is a scanning electron microscope image of an HfBOₓ film deposited in accordance with an embodiment of the invention.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention any of the film processing steps disclosed may also be performed on an underlayer formed on the substrate as disclosed in more detail below, and the term “substrate surface” is intended to include such underlayer as the context indicates.

As used herein, “room temperature” refers to a temperature range of about 20 to about 25° C.

The term “HfBOₓ” refers to a film containing hafnium, boron and oxygen. This term may be used interchangeably with HfBₓO_{y}. The film optionally contains hydrogen. Where the film contains hydrogen, the film may also be represented by the formula HfBₓO_{y}H_{z}.

As used herein, the phrase “atomic layer deposition” is used interchangeably with “ALD,” and refers to a process which involves sequential exposures of chemical reactants, and each reactant is deposited from the other separated in time and space. In ALD, chemical reactions take place only on the surface of the substrate in a stepwise fashion. However, according to one or more embodiments, the phrase “atomic layer deposition” is not necessarily limited to reactions in which each reactant layer deposited is limited to a monolayer (i.e., a layer that is one reactant molecule thick). The precursors in accordance with various embodiments of the invention will deposit conformal films regardless of whether only a single monolayer was deposited. Atomic layer deposition is distinguished from “chemical vapor deposition” or “CVD,” in that CVD refers to a process in which one or more reactants continuously form a film on a substrate by reaction in a process chamber containing the substrate or on the surface of the substrate. Such CVD processes tend to be less conformal than ALD processes.

In accordance with various embodiments of the invention, provided are methods related to the deposition of conformal hafnium containing films using a Hf(BH₄)₄ precursor and a co-reactant during an atomic layer deposition (ALD) process. The Hf(BH₄)₄ precursor is relatively volatile and reactive, which allows for the deposition of conformal hafnium-containing films at low temperature using a co-reactant. According to one or more embodiments, useful co-reactants include a source of oxygen. Examples of such co-reactants include, but are not limited to, water (H₂O), hydrogen peroxide (H₂O₂), ozone (O₃), mixtures of hydrogen peroxide and water (H₂O₂/H₂O), oxygen (O₂), mixtures of ozone and oxygen (O₃ in O₂) and other mixtures thereof. Use of these reactants produces a film comprising HfBOₓ. Other co-reactants may be used to vary the elemental content of the film. For example, ammonia may be used as a co-reactant to obtain films of hafnium, boron and nitrogen. Similarly, the closely related and analogous precursor Zr(BH₄)₄ may be used to deposit zirconium films using the same set of co-reactants using an analogous ALD process to produce directly analogous films.

Accordingly, one aspect of the invention relates to a method of depositing a metal-containing film. The method comprises sequentially exposing a substrate surface to alternating flows of a M(BH₄)₄ precursor and a co-reactant to provide a film. M is a metal selected from hafnium and zirconium. In some embodiments, the substrate surface may be exposed to the reactants co-reactants such that the substrate surface does not become fully saturated.

In one embodiment, M comprises hafnium. Where the co-reactant is an oxidant, the method will provide a film comprising hafnium, boron and oxygen. Alternatively, in another embodiment, M comprises zirconium. Where the co-reactant is an oxidant, the method will provide a film comprising zirconium, boron and oxygen.

In accordance with another embodiment, the co-reactant is ammonia (NH₃). Where M comprises hafnium, the film provided will comprise hafnium, boron and nitrogen. Alternatively, where M comprises zirconium, the film provided will comprise zirconium, boron and nitrogen.

According to various embodiments of the invention, the precursor can be represented by the formula M(BH₄)₄, where M is a metal. According to specific embodiments, M comprises Hf or Zr, and the precursors therefore comprise Hf(BH₄)₄ or Zr(BH₄)₄. In one method of synthesizing such M(BH₄)₄ precursors, HfCl₄ or ZrCl₄ is placed in an appropriate vessel (for example, a round bottom flask) and mixed with an excess of LiBH₄. A stir bar is added to the flask, and the mixture of two solids is stirred overnight. After stirring is completed, the product, also a white solid, can be optionally purified by sublimation and is transferred to an ampoule appropriate for delivery of the precursor to an ALD reactor.

As discussed above, different co-reactants may be used to vary the elemental content of the deposited film. In one embodiment, the co-reactant may be an oxidant. Suitable oxidant co-reactants include, but are not limited to, water (H₂O), hydrogen peroxide (H₂O₂), oxygen (O₂), and ozone (O₃), and mixtures thereof.

In embodiments where Hf(BH₄)₄ is used as the precursor and an oxidant is used as a co-reactant, the deposited films contain hafnium, boron, oxygen. The films may also contain hydrogen. In another embodiment, the co-reactant may be ammonia. Where the co-reactant is ammonia, the deposited films will contain hafnium, boron and nitrogen. The film may also contain hydrogen.

In embodiments where Zr(BH₄)₄ is used as the precursor and an oxidant is used as a co-reactant the films will contain zirconium, boron, oxygen and hydrogen. As with the hafnium precursor, in one embodiment, the co-reactant may be an oxidant. Suitable oxidant co-reactants include, but are not limited to, water, hydrogen peroxide, ozone, oxygen, and combinations thereof. In another embodiment, the co-reactant may be ammonia. Where the co-reactant is ammonia, the deposited films will contain zirconium, boron and nitrogen. The film may also contain hydrogen.

Another aspect of the invention relates to a film on a substrate, the film comprising a metal, boron and oxygen, wherein the metal comprises hafnium or zirconium. In a specific embodiment, the film comprises hafnium, boron and oxygen. In a further embodiment, the film further comprises hydrogen. In another embodiment, the film has an empirical formula of HfBₓO_{y}H_{z}. The variable x may have a value of from about 0 to about 4, and in a specific embodiment, a value of about 2. The variable y may have a value of from about 0 to about 10, and in a specific embodiment, about 2 to 10. In an alternative embodiment, y may have a value of about 0 to about 8, and in a specific embodiment, a value of about 0 to about 6. Finally, the variable z may have a range of from about 0 to about 10, and in a specific embodiment, about 4. In an alternative embodiment, the film comprises zirconium, boron and oxygen.

Yet another aspect of the invention relates to a method of depositing a metal-containing film by atomic layer deposition, the method comprising sequentially exposing a substrate to alternating pulses or flows of an Hf(BH₄)₄ precursor and a co-reactant comprising an oxidant to provide a film.

Co-reactants and process conditions may be selected to tune composition of the film, particularly the boron content.

In other embodiments, other co-reactants may be selected to allow the deposition of conductive metal alloy films. For example, in one embodiment, the co-reactant may be WF₆, which will provide films comprising hafnium, tungsten and boron (HfₓW_{y}Bₓ). Deposited alloys may be targeted to exhibit a specific work function desired for high K metal gate applications. In yet other embodiments, a silicon-containing co-reactant may be used to provide a silicon-containing film. For example, the M(BH₄)₄ precursor may be used with a silicon halide, such as SiBr₄ to produce films of MSiₓB_{y}, with BBr₃ and HBr byproducts. Another embodiment relates to films comprising MSnₓB_{y}, which could deposited using the M(BH₄)₄ precursor with SnCl₄, along with BCl₃ and HCl byproducts. Yet another embodiment relates to a film comprising MSₓB_{y}, deposited using a M(BH₄)₄ precursor with SF₆ co-reactant, with BF₃ and HF by product. Yet another embodiment relates to films of MRuₓB_{y}O_{z} from the M(BH₄)₄ precursor and RuO₄, with water as a byproduct.

Another feature of the films deposited according to one or embodiments, is very efficient utilization and incorporation of the precursor into the films. The resulting growth rates are about 2.7 Angstroms per cycle. In a specific embodiment, deposition processes employ only M(BH₄)₄ with H₂O as the co-reactant, and are applicable directly over oxygen very oxygen sensitive underlayers and liberate only H₂ and potentially B₂H₆ as volatile byproducts.

In exemplary embodiment of an ALD process, a first chemical precursor (“A”) is pulsed, for example, Hf(BH₄)₄ to the substrate surface in a first half reaction. Excess unused reactants and the reaction by-products are removed, typically by an evacuation-pump down and/or by a flowing inert purge gas. Then a co-reactant “B”, for example an oxidant or ammonia, is delivered to the surface, wherein the previously reacted terminating substituents or ligands of the first half reaction are reacted with new ligands from the “B” co-reactant, creating an exchange by-product. In some embodiments, the “B” co-reactant also forms self saturating bonds with the underlying reactive species to provide another self-limiting and saturating second half reaction. In alternative embodiments, the “B” co-reactant does not saturate the underlying reactive species. A second purge period is typically utilized to remove unused reactants and the reaction by-products. The “A” precursor, “B” co-reactants and purge gases can then again be flowed. The alternating exposure of the surface to reactants “A” and “B” is continued until the desired thickness film is reached, which for most anticipated applications would be approximately in the range of 5 nm to 40 nm, and more specifically in the range of 10 and 30 nm (100 Angstroms to 300 Angstroms). It will be understood that the “A”, “B”, and purge gases can flow simultaneously, and the substrate and/or gas flow nozzle can oscillate such that the substrate is sequentially exposed to the A, purge, and B gases as desired.

The precursors and/or reactants may be in a state of gas, plasma, vapor or other state of matter useful for a vapor deposition process. During the purge, typically an inert gas is introduced into the processing chamber to purge the reaction zone or otherwise remove any residual reactive compound or by-products from the reaction zone. Alternatively, the purge gas may flow continuously throughout the deposition process so that only the purge gas flows during a time delay between pulses of precursor and co-reactants.

Thus, in one or more embodiments, alternating pulses or flows of “A” precursor and “B” co-reactant can be used to deposit a film, for example, in a pulsed delivery of multiple cycles of pulsed precursors and co-reactants, for example, A pulse, B co-reactant pulse, A precursor pulse, B co-reactant pulse, A precursor pulse, B co-reactant pulse, A precursor pulse, B co-reactant pulse. As noted above, instead of pulsing the reactants, the gases can flow simultaneously from a gas delivery head or nozzle and the substrate and/or gas delivery head can be moved such that the substrate is sequentially exposed to the gases.

Of course, the aforementioned ALD cycles are merely exemplary of a wide variety of ALD process cycles in which a deposited layer is formed by alternating layers of precursors and co-reactants.

A deposition gas or a process gas as used herein refers to a single gas, multiple gases, a gas containing a plasma, combinations of gas(es) and/or plasma(s). A deposition gas may contain at least one reactive compound for a vapor deposition process. The reactive compounds may be in a state of gas, plasma, vapor, during the vapor deposition process. Also, a process may contain a purge gas or a carrier gas and not contain a reactive compound.

The films in accordance with various embodiments of this invention can be deposited over virtually any substrate material. As the ALD processes described herein are low-temperature, it is particularly advantageous to use these processes with substrates that are thermally unstable. A “substrate surface,” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride, aluminum, copper, or any other conductor or conductive or non-conductive barrier layer useful for device fabrication. Substrates may have various dimensions, such as 200 mm or 300 mm diameter wafers, as well as, rectangular or square panes. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers, III-V materials such as GaAs, GaN, InP, etc. and patterned or non-patterned wafers. Substrates may be exposed to a pretreatment process to polish, etch, reduce, oxidize, hydroxylate, anneal and/or bake the substrate surface.

As embodiments of the invention provide a method for depositing or forming hafnium and/or zirconium containing films, a processing chamber is configured to expose the substrate to a sequence of gases and/or plasmas during the vapor deposition process. The processing chamber would include separate supplies of the A and B reactants, along with any supply of carrier, purge and inert gases such as argon and nitrogen in fluid communication with gas inlets for each of the reactants and gases. Each inlet may be controlled by an appropriate flow controller such as a mass flow controller or volume flow controller in communication with a central processing unit (CPU) that allows flow of each of the reactants to the substrate to perform a ALD process as described herein. Central processing unit may be one of any forms of a computer processor that can be used in an industrial setting for controlling various chambers and sub-processors. The CPU can be coupled to a memory and may be one or more of readily available memory such as random access memory (RAM), read only memory (ROM), flash memory, compact disc, floppy disk, hard disk, or any other form of local or remote digital storage. Support circuits can be coupled to the CPU to support the CPU in a conventional manner. These circuits include cache, power supplies, clock circuits, input/output circuitry, subsystems, and the like.

The co-reactants are typically in vapor or gas form. The reactants may be delivered with a carrier gas. A carrier gas, a purge gas, a deposition gas, or other process gas may contain nitrogen, hydrogen, argon, neon, helium, or combinations thereof. Plasmas may be useful for depositing, forming, annealing, treating, or other processing of photoresist materials described herein. The various plasmas described herein, such as the nitrogen plasma or the inert gas plasma, may be ignited from and/or contain a plasma co-reactant gas.

In one or more embodiments, the various gases for the process may be pulsed into an inlet, through a gas channel, from various holes or outlets, and into a central channel. In one or more embodiments, the deposition gases may be sequentially pulsed to and through a showerhead. Alternatively, as described above, the gases can flow simultaneously through gas supply nozzle or head and the substrate and/or the gas supply head can be moved so that the substrate is sequentially exposed to the gases.

In another embodiment, a hafnium or zirconium containing film may be formed during plasma enhanced atomic layer deposition (PEALD) process that provides sequential pulses of a precursors and plasma. In specific embodiments, the co-reactant may involve a plasma. In other embodiments involving the use of plasma, during the plasma step the reagents are generally ionized during the process, though this might occur only upstream of the deposition chamber such that ions or other energetic or light emitting species are not in direct contact with the depositing film, this configuration often termed a remote plasma. Thus in this type of PEALD process, the plasma is generated external from the processing chamber, such as by a remote plasma generator system. During PEALD processes, a plasma may be generated from a microwave (MW) frequency generator or a radio frequency (RF) generator. Although plasmas may be used during the ALD processes disclosed herein, it should be noted that plasmas are not required. Indeed, other embodiments relate to ALD under very mild conditions without a plasma.

Another aspect of the invention pertains to an apparatus for deposition of a film on a substrate to perform a process according to any of the embodiments described above. In one embodiment, the apparatus comprises a deposition chamber for atomic layer deposition of a film on a substrate. The chamber comprises a process area for supporting a substrate. The apparatus includes a precursor inlet in fluid communication with a supply of a Hf(BH₄)₄ or Zr(BH₄)₄ precursor. The apparatus includes a reactant gas inlet in fluid communication with a supply of a co-reactant as discussed above. The apparatus further includes a purge gas inlet in fluid communication with a purge gas. The apparatus can further include a vacuum port for removing gas from the deposition chamber. The apparatus can further include an auxiliary gas inlet for supplying one or more auxiliary gases such as inert gases to the deposition chamber. The deposition can further include a means for heating the substrate by radiant and/or resistive heat.

In some embodiments, a plasma system and processing chambers or systems which may be used during methods described here for depositing or forming photoresist materials can be performed on either PRODUCER®, CENTURA®, or ENDURA® systems, all available from Applied Materials, Inc., located in Santa Clara, Calif. A detailed description of an ALD processing chamber may be found in commonly assigned U.S. Pat. Nos. 6,878,206, 6,916,398, and 7,780,785.

The ALD process provides that the processing chamber or the deposition chamber may be pressurized at a pressure within a range from about 0.01 Torr to about 100 Torr, for example from about 0.1 Torr to about 10 Torr, and more specifically, from about 0.5 Torr to about 5 Torr. Also, according to one or more embodiments, the chamber or the substrate may be heated such that deposition can take place at a temperature lower than about 200° C. In other embodiments, deposition may take place at temperatures lower than about 100° C., and in others, even as low as about room temperature. In one embodiment, deposition is carried out at a temperature range of about 50° C. to about 100° C.

A substrate can be any type of substrate described above. An optional process step involves preparation of a substrate by treating the substrate with a plasma or other suitable surface treatment to provide active sites on the surface of the substrate. Examples of suitable active sites include, but are not limited to 0-H, N-H, or S-H terminated surfaces. However it should be noted that this step is not required, and deposition according to various embodiments of the invention can be carried out without adding such active sites.

Delivery of “A” Precursor to Substrate Surface

The substrate can be exposed to the “A” precursor gas or vapor formed by passing a carrier gas (for example, nitrogen or argon) through an ampoule of the precursor, which may be in liquid form. The ampoule may be heated. The “A” precursor gas can be delivered at any suitable flow rate within a range from about 10 sccm to about 2,000 sccm, for example, from about 50 sccm to about 1,000 sccm, and in specific embodiments, from about 100 sccm to about 500 sccm, for example, about 200 sccm. The substrate may be exposed to the metal-containing “A” precursor gas for a time period within a range from about 0.1 seconds to about 10 seconds, for example, from about 1 second to about 5 seconds, and in a specific example, for approximately 2 seconds. The flow of the “A” precursor gas is stopped once the precursor has adsorbed onto all reactive surface moieties on the substrate surface. In an ideally behaved ALD process, the surface is readily saturated with the reactive precursor “A.”

First Purge

The substrate and chamber may be exposed to a purge step after stopping the flow of the “A” precursor gas. A purge gas may be administered into the processing chamber with a flow rate within a range from about 10 sccm to about 2,000 sccm, for example, from about 50 sccm to about 1,000 sccm, and in a specific example, from about 100 sccm to about 500 sccm, for example, about 200 sccm. The purge step removes any excess precursor, byproducts and other contaminants within the processing chamber. The purge step may be conducted for a time period within a range from about 0.1 seconds to about 8 seconds, for example, from about 1 second to about 5 seconds, and in a specific example, from about 4 seconds. The carrier gas, the purge gas, the deposition gas, or other process gas may contain nitrogen, hydrogen, argon, neon, helium, or combinations thereof. In one example, the carrier gas comprises nitrogen.

Delivery of “B” co-reactant to Substrate Surface

After the first purge, the substrate active sites can be exposed a “B” co-reactant gas or vapor formed by passing a carrier gas (for example, nitrogen or argon) through an ampoule the “B” co-reactant. The ampoule may be heated. The “B” reactant gas can be delivered at any suitable flow rate within a range from about 10 sccm to about 2,000 sccm, for example, from about 50 sccm to about 1,000 sccm, and in specific embodiments, at about 200 sccm. The substrate may be exposed to the “B” reactant gas for a time period within a range from about 0.1 seconds to about 8 seconds, for example, from about 1 second to about 5 seconds, and in a specific example, for about 2 seconds. The flow of the “B” reactant gas may be stopped once “B” has adsorbed onto and reacted with readily “A” precursor deposited in the preceding step.

Second Purge

The substrate and chamber may be exposed to a purge step after stopping the flow of the “B” co-reactant gas. A purge gas may be administered into the processing chamber with a flow rate within a range from about 10 sccm to about 2,000 sccm, for example, from about 50 sccm to about 1,000 sccm, and in a specific example, from about 100 sccm to about 500 sccm, for example, about 200 sccm. The purge step removes any excess precursor, byproducts and other contaminants within the processing chamber. The purge step may be conducted for a time period within a range from about 0.1 seconds to about 8 seconds, for example, from about 1 second to about 5 seconds, and in a specific example, from about 4 seconds. The carrier gas, the purge gas, the deposition gas, or other process gas may contain nitrogen, hydrogen, argon, neon, helium, or combinations thereof. In one example, the carrier gas comprises nitrogen. The “B” co-reactant gas may also be in the form of a plasma generated remotely from the process chamber.

There are various potential uses for the low temperature ALD processes described herein because of the films' superior qualities. Hafnium and zirconium containing films deposited according to various embodiments described herein are expected to be highly conformal. The hafnium and zirconium containing films can also be etch-resistant. In particular, HfBOₓ films exhibit high dry etch selectivity, particularly as compared to SiO₂-based films. Such films include spin-on siloxane based layers useful as antireflection coatings underneath a photoresist, or SiON layers, for example dielectric anti-reflective coating (DARC). As discussed above, SOO₂-based films cannot be used as underlayers for self-aligned double patterning approaches using low temperature ALD SiO₂ films, as they exhibit insufficient etch selectivity. Thus in one embodiment, the film is deposited onto a photoresist.

In certain embodiments, low temperature ALD of HfBOₓ films according to one or more embodiments described above is carried out over patterned photoresist films formed directly over the silicon-based dielectric layer. This allows for subsequent oxygen plasma strip steps to selectively remove the organic photoresist core layers without significant impact on the interface between the HfBOₓ film and the silicon-based dielectric film. Similarly, in certain embodiments, the photoresist pattern can be transferred through the underlying DARC hardmask film before the HfBOₓ ALD process to create nearly perfectly aligned complementary hard mask combinations.

An additional advantage to these hafnium and zirconium containing films is that these films may be deposited directly onto photoresist materials. Because deposition is carried out at low temperatures, there is little risk of damage to the photoresist material. Additionally, there is no need for higher-energy methods, such as plasma, which also minimizes the risk of photoresist damage.

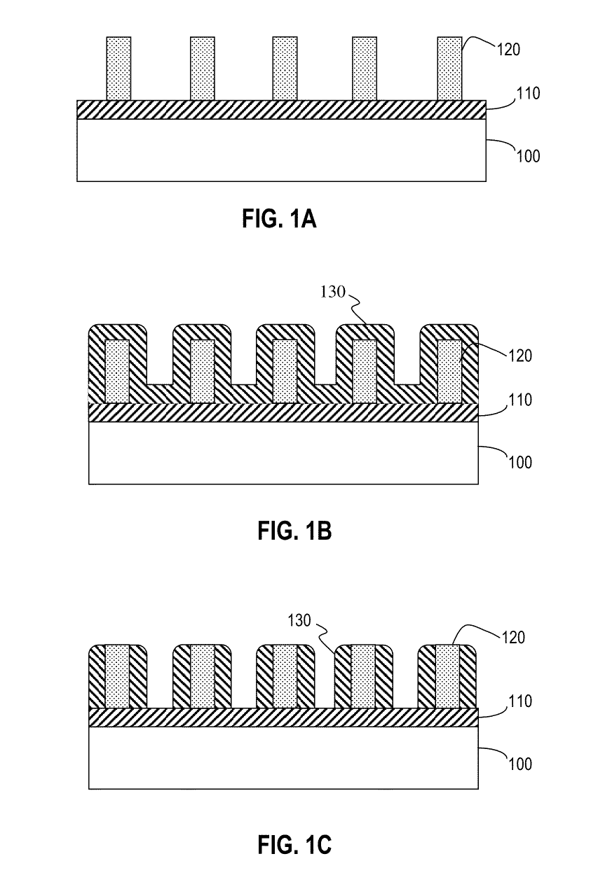

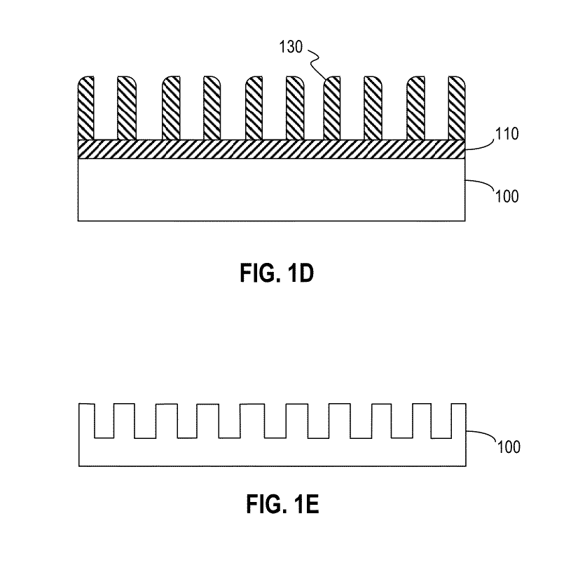

Accordingly, these films will work very well where such characteristics are desired, such as self-aligned double patterning (SADP) and quad patterning. FIGS. 1A-E show an example of such a SADP process. Turning to FIG. 1A, a substrate 100 is layered with a DARC layer 110. A photoresist is deposited onto the DARC layer 110 and patterned to provide patterned photoresist 120. As shown in FIG. 1B, a spacer film 130 can be deposited in accordance with one or more embodiments described herein onto the patterned photoresist 120 and DARC layers 110. For example, spacer film 130 can be a HfBOₓ film deposited using a Hf(BH₄)₄ precursor and an oxidant co-reactant. In FIG. 1C, the spacer film 130 is etched to form the spacers by removing spacer film 130 from horizontal surfaces. Turning to FIG. 1D, the original patterned photoresist 120 is etched away, leaving only what is left of spacer film 130. Then substrate 100 can be etched using the spacers as a guide, and the remaining DARC 110 and spacer film 130 stripped to provide the etched substrate 100 in FIG. 1E. The selectivity between the films described herein, such as HfBOₓ film, allows for this process to be carried out. As described above, where there is not such selectivity, a cap, such as SiON, must be placed on the photoresist prior to the deposition of the spacer film. These caps prevent unintentionally etching away patterned photoresist.

An additional benefit with films deposited according to one or more embodiments described herein is related to an inherent selectivity of certain surfaces for promoting reactions of the volatile precursors, including those reactions leading to deposition. For example, in the absence of co-reactants of the type used to deposit HfBOₓ dielectric layers, the Hf(BH₄)₄ precursor can exhibit selective decomposition over the surface of late transition metals to form films of HfB₂, as well as potentially mixed metal alloy phases.

Yet another application of the films and methods described herein are in organic light emitting diodes (OLEDs), which are light-emitting diodes in which the emissive electroluminescent layer is a film of organic compounds. This layer of organic compounds emits light in response to an electric current. A problem with OLEDs has been the necessity of ensuring hermetic seals/encapsulation to avoid degradation from air and moisture. However, the films described herein may provide a solution for OLED passivation because the films, according to the various embodiments of the invention, can initiate and grow over a wide temperature range (including room temperature), and can provide oxygen-free conditions for the deposition of robust, pinhole-free amorphous dielectric glass. This is particularly true in embodiments where H₂O is used as the co-reactant (under non-oxidizing conditions) as the only source of oxygen. In a particular embodiment, the co-reactant comprises H₂O, and the flow of co-reactant does not fully saturate the surface. It is thought that this will minimize the potential for undesired infiltration of H₂O into sensitive OLED layers.

It is also possible to obtain good air and moisture barrier properties. In a related embodiment, the deposited film is oxygen deficient (and hydrogen rich), allowing for an O₂ and/or H₂O gettering effect. In a particular embodiment, the co-reactant flow does not saturate the substrate surface, particularly at the beginning of a deposition sequence (and the underlayer is still exposed).

### EXAMPLES

### Example 1

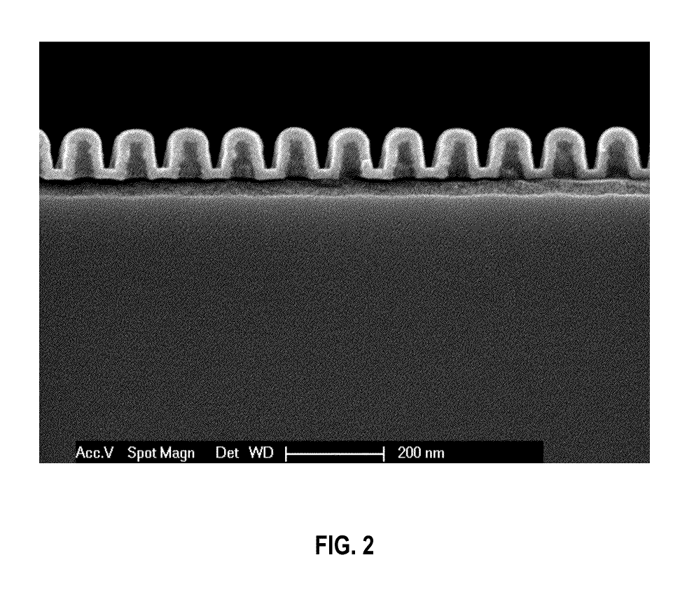

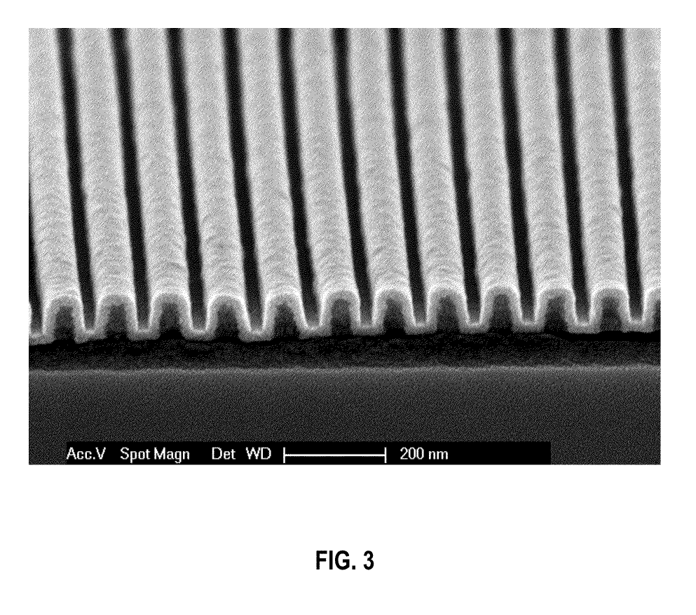

A film was deposited onto a patterned silicon wafer using a Hf(BH₄)₄ precursor and water. The wafer was heated to 100 degrees C. A bare silicon wafer coated with an organic BARC and patterned photoresist was used as the substrate. The hafnium precursor was pulsed into the chamber for 0.5 seconds at a pressure of one torr. Five seconds later, the chamber was evacuated and purged with nitrogen. Water was then pulsed into the chamber for one second at a pressure of 16 torr. Again, after 5 seconds, the chamber was evacuated and purged with nitrogen. This sequence was repeated for 75 cycles. The resulting film was 221 Å thick, for a growth per cycle of about 2.9 Å. The index of refraction of the film was measured to be 1.68 at 633 nm. The film was deposited without the use of plasma. FIGS. 2 and 3 are scanning electron microscopic pictures of the deposited film from two different viewpoints. As seen in this figure, the film is highly conformal.

### Example 2

A film was deposited onto a patterned silicon wafer using a Hf(BH₄)₄ precursor and a mixture of 30% H₂O₂ in water. The chamber was heated to a temperature of 100 degrees C. A bare silicon wafer was used as the substrate. The hafnium precursor was pulsed into the chamber for 0.5 seconds at a pressure of 1.7 torr. Thirty seconds later, the chamber was evacuated, and purged with nitrogen. The water peroxide mixture was then pulsed into the chamber for one second at a pressure of 16 torr. Again, after 30 seconds, the chamber was evacuated and purged with nitrogen. This sequence was repeated for 75 cycles. The resulting film was 233 Å thick, for a growth per cycle of about 3.11 angstroms per cycle. The index of refraction of the film was measured to be 1.67 at 633 nm. Rutherford backscattering (RBS), nuclear reaction analysis (NRA), and hydrogen forward scattering spectrometry (HFS) analysis showed the film to contain approximately 7.3 atomic %, hafnium, 48.4% oxygen, 25% boron, 19.3% hydrogen.

### Example 3

A film was deposited onto a patterned silicon wafer using a Hf(BH₄)₄ precursor and water co-reactant. The chamber was unheated and allowed to operate at room temperature. A bare silicon wafer was used as the substrate. The hafnium precursor was pulsed into the chamber for 0.5 seconds at a pressure of one torr. Five seconds later, the chamber was evacuated, and purged with nitrogen. The water was then pulsed into the chamber for one second at a pressure of 16 torr. Again, after 5 seconds, the chamber was evacuated and purged with nitrogen. This sequence was repeated for 75 cycles. The resulting film was 363.2 Å thick, for a growth per cycle of about 4.8 angstroms. The index of refraction of the film was measured to be 1.63 at 633 nm.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A film on a substrate, the film comprising a hafnium, boron and oxygen.

2. The film of claim 1, further comprising hydrogen.

3. The film of claim 2, wherein the film has an empirical formula of HfBₓO_{y}H_{z}, and wherein x has a value of from about 0 to about 4, y has a value of from about 0 to about 10, and z has a range of from about 0 to about 10.

4. A method of depositing a metal-containing film, the method comprising sequentially exposing a substrate surface to alternating flows of a M(BH₄)₄ precursor and a co-reactant to provide a film, wherein M is a metal selected from hafnium and zirconium.

5. The method of claim 4, wherein the co-reactant comprises an oxidant.

6. The method of claim 5, wherein the oxidant is selected from H₂O, H₂O₂, O₂, O₃, and mixtures thereof.

7. The method of claim 4, wherein M is hafnium.

8. The method of claim 7, wherein the co-reactant comprises an oxidant and the film comprises hafnium, boron and oxygen.

9. The method of claim 4, wherein M is zirconium.

10. The method of claim 9, wherein the co-reactant comprises an oxidant and the film comprises zirconium, boron and oxygen.

11. The method of claim 4, wherein the co-reactant comprises NH₃.

12. The method of claim 11, wherein M is hafnium, and the film comprises hafnium, boron and nitrogen.

13. The method of claim 4, wherein the method is carried out at a temperature of less than about 200° C.

14. The method of claim 13, wherein the temperature has a range of about room temperature to about 100° C.

15. The method of claim 4, wherein the film is deposited onto a photoresist.

16. The method of claim 4, wherein the co-reactant is selected from WF₆ and RuO₄.

17. The method of claim 16, wherein the film comprises M, tungsten and boron.

18. The method of claim 16, wherein the deposited film comprises M, ruthenium, boron and oxygen.

19. The method of claim 4, wherein the co-reactant flow does not fully saturate the substrate surface.

20. A method of depositing a metal-containing film, the method comprising sequentially exposing a substrate to alternating flows of a Hf(BH₄)₄ precursor and a co-reactant comprising an oxidant to provide a film.
